(19) United States
(12) Patent Application Publication
(10) Pub. No.: US 2011/0018135 A1
(43) Pub. Date: Jan. 27, 2011

(54) METHOD OF ELECTRICALLY CONNECTING A WIRE TO A PAD OF AN INTEGRATED CIRCUIT CHIP AND ELECTRONIC DEVICE

(75) Inventors: Romain Coffy, Saint Martin Le Vinoux (FR); Fabien Quercia, Echirolles (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMICROELECTRONICS (GRENOBLE 2) SAS, Grenoble (FR)

(21) Appl. No.: 12/843,515

(22) Filed: Jul. 26, 2010

(30) Foreign Application Priority Data
Jul. 27, 2009 (FR) 0955237

(51) Int. Cl. H01L 23/498; B23K 1/20

(52) U.S. Cl. 257/762; 228/256; 257/E23.073

(57) ABSTRACT

A wire is electrically connected to an electrical bonding pad of an integrated circuit chip and electronic device through an intermediate electrical interconnect block that is interposed between the electrical bonding pad and one end of the electrical lead wire.

### PRIORITY CLAIM

This application claims priority from French Application for patent No. 09-55237 filed Jul. 27, 2009, the disclosure of which is hereby incorporated by reference.

### TECHNICAL FIELD

The present invention relates to the field of integrated circuit chips and packages comprising such chips, and more particularly to the wire means used to electrically link such chips to other means or devices.

### SUMMARY

A method of electrically connecting a wire to an electrical bonding pad of an integrated circuit chip is proposed.

An electrical connection method may comprise the placing of an intermediate electrical interconnect block on said electrical bonding pad and the placing of one end of the electrical lead wire on the intermediate interconnect block.

The method may comprise the choice, for the interconnect block, of a material more malleable or ductile than that of the electrical lead wire and/or of the electrical bonding pad.

The method may comprise the formation of a ball at the end of a secondary wire, the placing of this ball on the electrical bonding pad in order to form the interconnect block and the breaking of the secondary wire at a point adjacent or close to the interconnect block.

The method may comprise the formation of a ball at the end of the electrical lead wire and the placing of this ball on the interconnect block.

Before the placing of the end of the electrical lead wire, the interconnect block may have a front face approximately parallel to that of the electrical bonding pad.

The interconnect block may be soldered to the electrical bonding pad.

The electrical lead wire may be soldered to the interconnect block.

The electrical bonding pad may be chosen to be made of aluminum, the interconnect block may be chosen to be made of gold and the electrical lead wire may be chosen to be made of copper, or alternatively alloys of such materials.

An electronic device comprising an integrated circuit chip is also proposed, that comprises at least one electrical bonding pad, an intermediate electrical interconnect block soldered to the electrical bonding pad, and an electrical lead wire, one end of which is soldered to the interconnect block.

The interface between the interconnect block and the end of the electrical lead wire may be approximately parallel to the face of the electrical bonding pad.

The electrical lead wire may comprise a ball soldered to the interconnect block.

The diameter of the interconnect block and that of the end of the electrical lead wire may be between 1.5 and 3 times the diameter of the electrical lead wire.

The interconnect block may be made of a material more malleable or ductile than that of the electrical lead wire and/or of the electrical bonding pad.

The pad may be made of aluminum or an aluminum-based alloy, the interconnect block may be made of gold or a gold-based alloy and the electrical lead wire may be made of copper or a copper-based alloy.

An electronic package comprising at least one device as described hereinabove is also proposed.

### BRIEF DESCRIPTION OF THE DRAWINGS

An electronic device comprising an integrated circuit chip and an electrical lead wire will now be described by way of non-limiting example, and illustrated by the drawing in which:

FIG. 1 represents an elevation view of an electronic device;

FIG. 2 represents a first mounting phase for this device;

FIG. 3 represents a second mounting phase for this device;

FIG. 4 represents a third mounting phase for this device;

FIG. 5 represents a fourth mounting phase for this device; and

FIG. 6 represents a fifth mounting phase for this device.

### DETAILED DESCRIPTION OF THE DRAWINGS

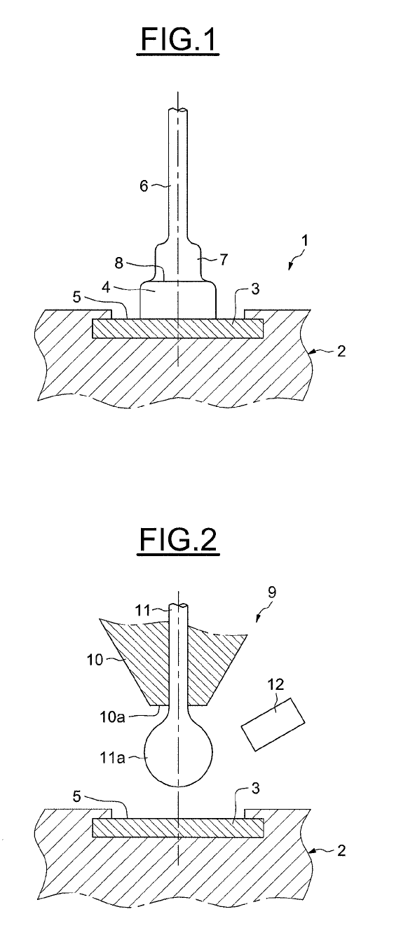

An electronic device 1, represented in FIG. 1, comprises an integrated circuit chip 2 which comprises a plurality of external electrical bonding pads 3 in order to connect this chip to other means or devices.

The semiconductor device 1 also comprises, on each pad 3, an intermediate electrical interconnect block 4 soldered to an external flat face 5 of the pad 3.

The semiconductor device 1 also comprises a plurality of electrical lead wires 6, each wire 6 having an enlarged end 7 soldered to an interconnect block 4.

The interface 8 between the electrical interconnect block 4 and the end 7 of the electrical lead wire 6 may be approximately parallel to the face 5 of the pad 3.

The link between the intermediate interconnect block 4 and the pad 3 and the link between the end 7 of the electrical lead wire 6 and the intermediate interconnect block 4 may be made by a eutectic solder joint.

In a first step, the intermediate interconnect block 4 may be placed on the pad 3, then, in a second step, the end 7 of the electrical lead wire 6 may be placed on the intermediate interconnect block 4.

By way of example, these placing operations may be carried out as follows.

As shown in FIG. 2, a tool 9 may have a head 10 with a secondary wire 11 passing through it that is made of a material that is required to form the interconnect block 4. With this secondary wire 11 extending downward, a means 12 of the tool 9, able for example to generate a heating electric arc, makes it possible to form a ball 11a at the end of the wire 11.

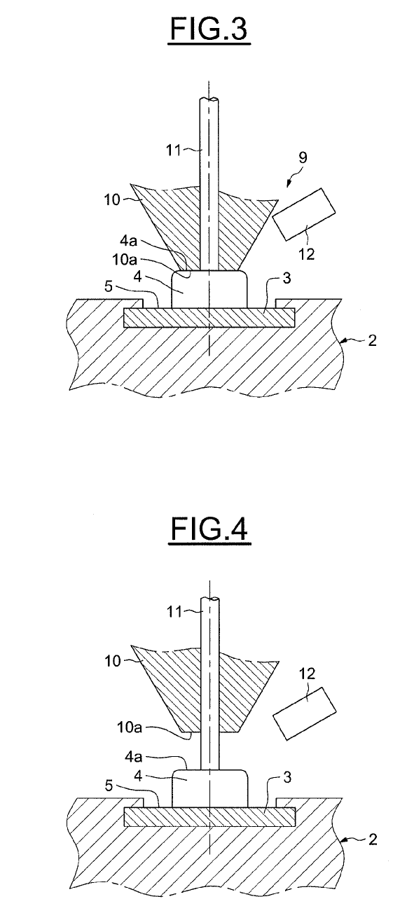

As shown in FIG. 3, the head 10 of the tool 9 may be moved towards the pad 3 so as to squeeze the ball 11a onto the surface 5 of this pad 3 by exerting pressure, lightly but sufficiently for the annular front face 10a of the head 10, parallel to the face 5 of the pad 3, to be applied to the ball 11a to form on the latter a face 4a. This operation, which may be carried out with added heat and possibly under the effect of ultrasound, causes a eutectic solder joint or bond between the interconnect block 4 and the pad 3.

Thereafter, as shown in FIG. 4, the head 10 may be slightly raised, by sliding along the secondary wire 11, and the means 12 of the tool 9 may be activated to generate a heating electric arc to cause the secondary wire 11 to break at a point adjacent or close to the duly formed interconnect block 4, by distancing the head 10 from the tool 9.

The ball 11a is thus transformed in order to form the interconnect block 4, which is approximately in the form of a cylinder or a truncated cone whose large base is on the pad 3, the front face 4a of the interconnect block 4 being approximately parallel to the face 5 of the pad 3.

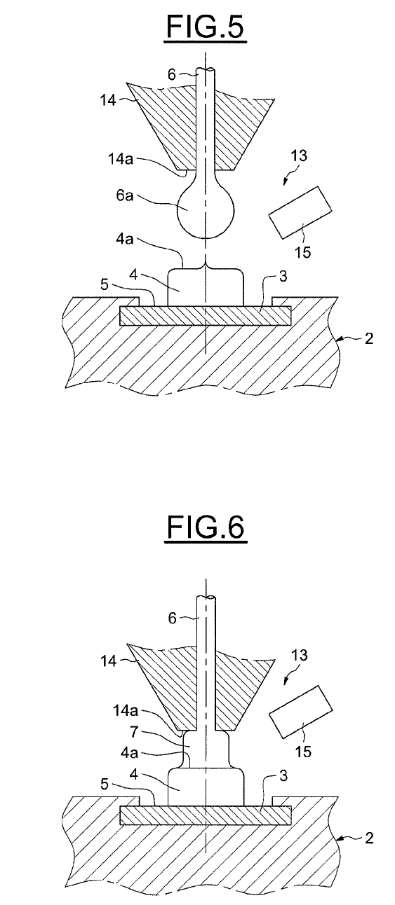

That having been done, as shown in FIG. 5, a tool 13 may have a head 14 with an electrical lead wire 6 passing through it. With this electrical lead wire 6 extending downwards, a means 15 of the tool 13, able for example to generate a heating electric arc, makes it possible to form a ball 6a at the end of the electrical lead wire 6. This ball 6a may be smaller than the ball 11a used to form the interconnect block 4.

As shown in FIG. 6, the head 14 of the tool 13 may be moved towards the duly formed interconnect block 4, so as to squeeze the ball 6a onto the front surface 4a of this interconnect block 4 by exerting pressure, lightly but sufficiently. This operation, which may be carried out with added heat and possibly under the effect of ultrasound, causes a eutectic solder joint or a bond between the ball 6a and the interconnect block, this ball 6a then forming the enlarged end 7.

Thereafter, the head 14 of the tool 13 may be moved along the electrical lead wire 6 and used to solder another point of this wire onto a pad, for example of another means that is not represented.

The above operations may be carried out on the other interconnect blocks 5 of the chip 2.

The diameter of the secondary wire 11 may be greater than the diameter of the electrical lead wire 6. The ball 11a that is formed at the end of the secondary wire 11 may be larger than the ball 6a that is formed at the end of the electrical lead wire 6. This may make it possible for the enlarged end 7 of the lead wire 6 to be correctly formed on the interconnect block 4. The diameter of the secondary wire 11 may be equal to or greater than the diameter of the electrical lead wire 6.

The result of the above is that providing an interconnect block 4 between the pad 3 of the integrated circuit chip 2 and the electrical lead wire 6 makes it possible to choose materials which normally do not allow a strong and stable direct bond between one another to form the pad 3 and the lead wire 6.

It is in fact made possible to choose materials that are able to create a strong stable bond between one another for the pad 3 and the interconnect block 4, and also materials that are able to create a strong stable bond between one another to form the interconnect block 4 and the lead wire 6.

Moreover, it is also made possible to choose a material more malleable or ductile than that of the pad 3 and/or of the electrical lead wire 6 for the interconnect block 4. This makes it possible to limit the compressive stresses on the chip 2.

Furthermore, the pitch between the electrical bonding pads 3 of a chip 2 may be reduced.

By way of example, the electrical bonding pad 3 may be made of aluminum, the electrical interconnect block 4 may be made of gold and the electrical lead wire 6 may be made of copper. Alloys may also be used. The existence of a gold electrical interconnect block makes it possible to obviate the difficulties associated with directly soldering a copper electrical lead wire onto an aluminum electrical bonding pad.

According to one embodiment, the diameter of the interconnect block 4 and the diameter of the end 7 of the electrical lead wire 6 may be approximately between 1.5 and 3 times the current diameter of the electrical lead wire 6. The diameter of the interconnect block 4 may be smaller than the diameter of the end 7 of the electrical lead wire 6. The height of the interconnect block 4 and the height of the end 7 of the electrical lead wire 6 may be approximately between 0.75 and 2 times the current diameter of the electrical lead wire 6.

In particular, the current diameter of the electrical lead wire 6 may be between 20 and 25 microns, the diameter of the interconnect block 4 may be between 40 and 45 microns, the height of the interconnect block 4 may be between 20 and 25 microns, and the diameter of the end 7 of the electrical lead wire 6 may be between 35 and 40 microns.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method of electrically connecting an electrical connecting wire to an electrical bonding pad of an integrated circuit chip, comprising:
forming a first ball at an end of a secondary wire;
placing the first ball on the electrical bonding pad in order to form an intermediate interconnect block;
breaking of the secondary wire at a point adjacent or close to the intermediate interconnect block, this interconnect block having a front face parallel to the face of the electrical bonding pad;
forming a second ball at an end of the electrical connecting wire;
placing the second ball on the front face of the intermediate interconnect block for forming an enlarged end of the electrical connecting wire on the intermediate interconnect block;
wherein the diameter of the secondary wire is greater than the diameter of the electrical connecting wire; and
wherein the ball formed at the end of the secondary wire is bigger than the ball formed at the end of the electrical connecting wire.

2. The method according to claim 1, wherein the interconnect block is made of a material more malleable or ductile than that of the electrical lead wire.

3. The method according to claim 1, wherein the interconnect block is made of a material more malleable or ductile than the electrical bonding pad.

4. The method according to claim 1, further comprising soldering the interconnect block to the electrical bonding pad.

5. The method according to claim 1, further comprising soldering the electrical lead wire to the interconnect block.

6. The method according to claim 1, wherein the electrical bonding pad is made of aluminum or an aluminum-based alloy, the interconnect block is made of gold or a gold-based alloy and the electrical connecting wire is made of copper or a copper-based alloy.

7. The method according to claim 1, wherein the intermediate electrical interconnect block has a shape in the form of a cylinder or truncated cone.

8. The method according to claim 7, further comprising forming the enlarged end of the electrical connecting wire to have a shape in the form of a cylinder or truncated cone that is smaller than the shape of the intermediate electrical interconnect block.

9. An electronic device comprising:
an integrated circuit chip comprising at least one electrical bonding pad,
an intermediate electrical interconnect block soldered to the electrical bonding pad, and
an electrical lead wire, one end of which is soldered to the interconnect block;
wherein an interface between the interconnect block and the end of the electrical lead wire is approximately parallel to a face of the electrical bonding pad.

10. The device according to claim 9, wherein the one end of the electrical lead wire comprises a ball soldered to the interconnect block.

11. The device according to claim 9, wherein a diameter of the interconnect block and a diameter of the one end of the electrical lead wire are between 1.5 and 3 times a diameter of the electrical lead wire.

12. The device according to claim 9, wherein the interconnect block is made of a material more malleable or ductile than a material of the electrical lead wire.

13. The device according to claim 9, wherein the interconnect block is made of a material more malleable or ductile than a material of the electrical bonding pad.

14. The device according to claim 9, wherein the pad is made of aluminum or an aluminum-based alloy, the interconnect block is made of gold or a gold-based alloy and the electrical lead wire is made of copper or a copper-based alloy.

15. An electronic device comprising:
an integrated circuit chip comprising at least one electrical bonding pad having a front surface,
an intermediate electrical interconnect block having a shape in the form of a cylinder or truncated cone that is attached to the front surface of the electrical bonding pad, and
an electrical lead wire having a first diameter and including an attachment end having a second diameter larger that the first diameter, the attachment end being attached to the interconnect block.

16. The device of claim 15 wherein the attachment end of the electrical lead wire has a shape in the form of a cylinder or truncated cone.

17. The device of claim 15, wherein the second diameter is between 1.5 and 3 times the first diameter.

18. The device of claim 15, wherein the intermediate electrical interconnect block has a diameter that is between 1.5 and 3 times the first diameter.

19. The device of claim 18 wherein the diameter of the intermediate electrical interconnect block is greater than the second diameter.

20. The device of claim 15, wherein the pad is made of aluminum or an aluminum-based alloy, the interconnect block is made of gold or a gold-based alloy and the electrical lead wire is made of copper or a copper-based alloy.
